(19) United States
(12) Patent Application Publication
(10) Pub. No.: US 2026/0271403 A1
(43) Pub. Date: Sep. 10, 2026

(54) DISPLAY DEVICE AND METHOD FOR PRODUCING DISPLAY DEVICE

(71) Applicant: Sharp Display Technology Corporation, Kameyama City, Mie (JP)

(72) Inventor: Kazuatsu ITO, Kameyama City, Mie (JP)

(21) Appl. No.: 19/111,000

(22) PCT Filed: Sep. 13, 2022
(86) PCT No.: PCT/JP2022/034146

§ 371 Date: Mar. 12, 2025

(51) Int. Cl. H10D 86/40

(52) U.S. Cl. CPC H10D 86/441; H10D 86/423

(57) ABSTRACT

A display device includes a substrate; a conductive film positioned above the substrate; an oxide semiconductor film positioned above the conductive film and including a channel portion and a conductor portion, the conductor portion being in contact with the conductive film; an interlayer insulating film positioned above the oxide semiconductor film and including a contact hole overlapping the conductive film in a plan view; and a contact electrode including a portion located in the contact hole and positioned above the interlayer insulating film. The contact electrode is in contact with respective exposed faces of the conductive film and the conductor portion formed by the contact hole.

### TECHNICAL FIELD

The disclosure relates to a display device and a method of manufacturing the display device.

### BACKGROUND ART

PTL 1 discloses a display device including a metal film positioned above a substrate and an oxide semiconductor film positioned above the metal film and including a channel portion and a conductor portion.

### CITATION LIST

### Patent Literature

PTL 1: WO 2020/217477 Pamphlet

### SUMMARY

### Technical Problem

Due to oxidation of the metal film or step disconnection of the oxide semiconductor film at an end face of the metal film, there is a possibility that a contact failure may occur between the metal film and the oxide semiconductor film.

### Solution to Problem

In order to solve the above problem, a display device according to an aspect of the disclosure includes: a substrate; a conductive film positioned above the substrate; an oxide semiconductor film positioned above the conductive film and including a channel portion and a conductor portion, the conductor portion being in contact with the conductive film; an interlayer insulating film positioned above the oxide semiconductor film and including a contact hole overlapping the conductive film in a plan view; and a contact electrode including a portion located in the contact hole and positioned above the interlayer insulating film, in which the contact electrode is in contact with respective exposed faces of the conductive film and the conductor portion formed by the contact hole.

In order to solve the above problem, a display device according to an aspect of the disclosure includes: a substrate; a conductive film positioned above the substrate; an oxide semiconductor film positioned above the conductive film and including a channel portion and a conductor portion, the conductor portion covering an end face of the conductive film, the conductor portion being in contact with the conductive film, an interlayer insulating film positioned above the oxide semiconductor film and including a contact hole overlapping the end face in a plan view; and a contact electrode including a portion located in the contact hole and being in contact with the conductor portion.

In order to solve the above problem, a display device according to an aspect of the disclosure includes: a substrate; a conductive film positioned above the substrate; an oxide semiconductor film positioned above the conductive film and including a channel portion and a conductor portion, the conductor portion overlapping the conductive film in a plan view; and a buffer film located between the conductive film and the conductor portion and including an oxide semiconductor including an oxygen content lower than that of the conductor portion.

In order to solve the above problem, a method of manufacturing a display device according to an aspect of the disclosure includes forming the buffer film and the oxide semiconductor film continuously.

### Advantageous Effects of Disclosure

According to an aspect of the disclosure, an increase in contact resistance between the metal film and the oxide semiconductor film can be suppressed.

### BRIEF DESCRIPTION OF DRAWINGS

FIG. 1 is a schematic plan view illustrating a configuration of a display device according to the present embodiment.

FIG. 2 is a cross-sectional view of a main portion of the display device according to the present embodiment.

FIG. 3 is a circuit diagram illustrating an example of a pixel circuit provided in the above display device.

FIG. 4 is a cross-sectional view of a display device according to a first embodiment.

FIG. 5 is a plan view corresponding to the above cross-sectional view.

FIG. 6 is a cross-sectional view of a display device according to a comparative example.

FIG. 7 is a plan view of the above display device.

FIG. 8 is a cross-sectional view of a display device according to a second embodiment.

FIG. 9 is a plan view corresponding to the above cross-sectional view.

FIG. 10 is a cross-sectional view of a display device according to a third embodiment.

FIG. 11 is a plan view corresponding to the above cross-sectional view.

FIG. 12 is a cross-sectional view of a display device according to a fourth embodiment.

FIG. 13 is a plan view corresponding to the above cross-sectional view.

FIG. 14 is a cross-sectional view of a display device according to a fifth embodiment.

FIG. 15 is a plan view corresponding to the above cross-sectional view.

FIG. 16 is a cross-sectional view of a display device according to a sixth embodiment.

FIG. 17 is a plan view corresponding to the above cross-sectional view.

### DESCRIPTION OF EMBODIMENTS

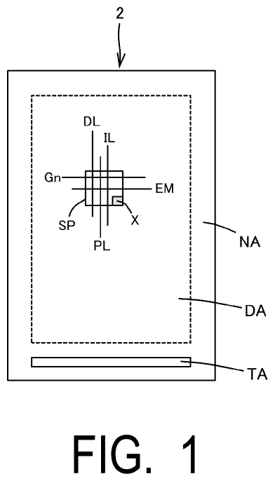

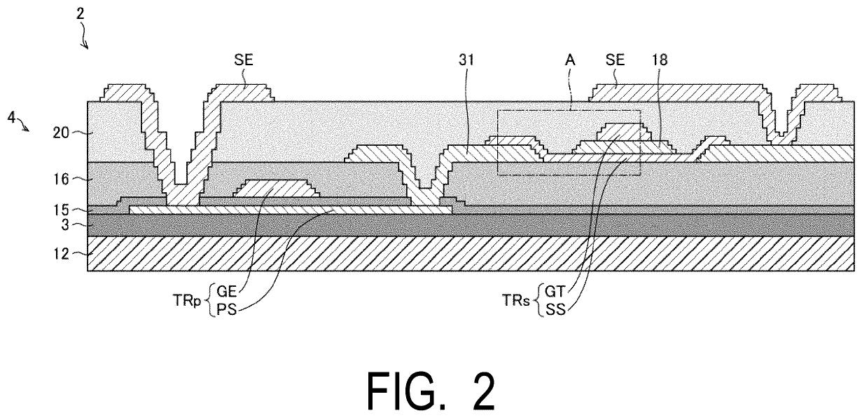

FIG. 1 is a schematic plan view illustrating a configuration of a display device 2 according to the present embodiment. FIG. 2 is a cross-sectional view of a main portion of the display device 2.

As illustrated in FIG. 1 and FIG. 2, in the display device 2, a base coat film 3, a thin film transistor (TFT) layer 4, a light-emitting element layer of a top-emitting (emitting light to an upper-layer side) type, and a sealing layer are formed in this order on a substrate 12. Note that, illustration of the light-emitting element layer and the sealing layer are omitted in FIG. 2.

A plurality of subpixels SP each including a light-emitting element X are formed in a display region DA. A frame region NA surrounding the display region DA is provided with a terminal portion TA.

As illustrated in FIG. 2, the thin film transistor layer 4 includes a crystalline silicon semiconductor film PS positioned above the base coat film 3, a first gate insulating film 15 positioned above the crystalline silicon semiconductor film PS, a first gate electrode GE made of a first metal layer and positioned above the first gate insulating film 15, a first interlayer insulating film 16 positioned above the first metal layer, a first electrode 31 (conductive film) made of a second metal layer and positioned above the first interlayer insulating film 16, an oxide semiconductor film SS positioned above the second metal layer, a second gate insulating film 18 positioned above the oxide semiconductor film SS, a second gate electrode GT positioned above the second gate insulating film 18 and made of a third metal layer, a second interlayer insulating film 20 positioned above the third metal layer, a second electrode SE positioned above the second interlayer insulating film 20 and made of a fourth metal layer, and a flattening film (not illustrated) positioned above the fourth metal layer.

The crystalline silicon semiconductor film PS is formed of, for example, low-temperature polysilicon (LTPS). The oxide semiconductor film SS includes at least one type of element selected from, for example, indium (In), gallium (Ga), tin (Sn), hafnium (Hf), zirconium (Zr), and zinc (Zn), and oxygen. Specifically, an oxide semiconductor (InGaZnO) including indium (In), gallium (Ga), zinc (Zn), and oxygen, an oxide semiconductor (InSnZnO) including indium (In), tin (Sn), zinc (Zn), and oxygen, an oxide semiconductor (InZrZnO) including indium (In), zirconium (Zr), zinc (Zn), and oxygen, an oxide semiconductor (InHfZnO) including indium (In), hafnium (Hf), zinc (Zn), and oxygen, or the like can be used.

In FIG. 2, a second transistor TRp is formed to include the first gate electrode GE and the crystalline silicon semiconductor film PS, and a first transistor TRs is formed to include the second gate electrode GT and the oxide semiconductor film SS.

The first metal layer, the third metal layer, and the fourth metal layer are each formed of a single metal layer film or a plurality of metal layer films including at least one of aluminum, tungsten, molybdenum, tantalum, chromium, titanium, and copper, for example. The second metal layer is formed of, for example, a metal film made of tungsten, molybdenum, or titanium.

The first interlayer insulating film 16, the first gate insulating film 15, the second gate insulating film 18, and the second interlayer insulating film 20 can be formed of a silicon oxide (SiOx) film, a silicon nitride (SiNx) film or a layered film thereof formed by CVD, for example. The flattening film can be formed of, for example, a coatable organic material such as a polyimide resin or an acrylic resin.

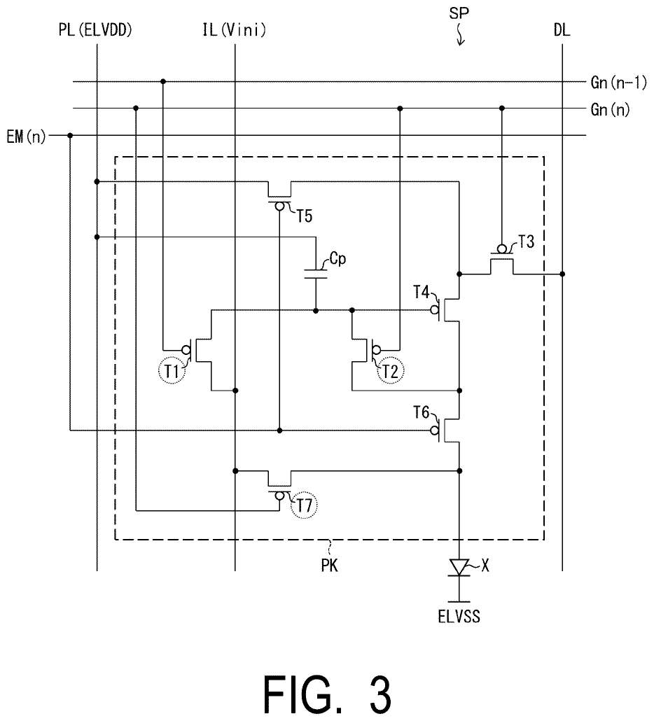

FIG. 3 is a circuit diagram illustrating an example of a pixel circuit PK provided in the display device 2. In the display region DA in FIG. 1, a light-emitting element X and its pixel circuit PK are provided for each of the subpixels SP, and in the thin film transistor layer 4, the pixel circuit PK and a wiring line connected thereto are formed.

The pixel circuit PK in FIG. 3 includes a capacitor Cp, a first initialization transistor T1 including a gate terminal connected to a scanning signal line Gn(n-1) at a previous stage ((n-1)-th stage), a threshold value control transistor T2 including a gate terminal connected to a scanning signal line Gn(n) at an own stage (n-th stage), a writing control transistor T3 including a gate terminal connected to the scanning signal line Gn(n) at the own stage (n-th stage), a drive transistor T4 configured to control a current of the light-emitting element X, a power supply transistor T5 including a gate terminal connected to a light emission control line EM(n) at the own stage (n-th stage), a light emission control transistor T6 including a gate terminal connected to the light emission control line EM(n) at the own stage (n-th stage), and a second initialization transistor T7 including a gate terminal connected to the scanning signal line Gn(n) at the own stage (n-th stage).

A gate terminal of the drive transistor T4 is connected to a high-voltage side power source line (also serves as a first initialization power source line) PL via the capacitor Cp, and is connected to a second initialization power source line IL via the first initialization transistor T1. A source terminal of the drive transistor T4 is connected to a data signal line DL via the writing control transistor T3, and is connected to the high-voltage side power source line PL via the power supply transistor T5. A drain terminal of the drive transistor T4 is connected to the gate terminal of the drive transistor T4 via the threshold value control transistor T2, and is connected to an anode of the light-emitting element X via the light emission control transistor T6. The anode of the light-emitting element X is connected to the second initialization power source line IL via the second initialization transistor T7. The second initialization power source line IL and a cathode (common electrode) of the light-emitting element X are supplied with, for example, the same low-voltage side power source (ELVSS).

### First Embodiment

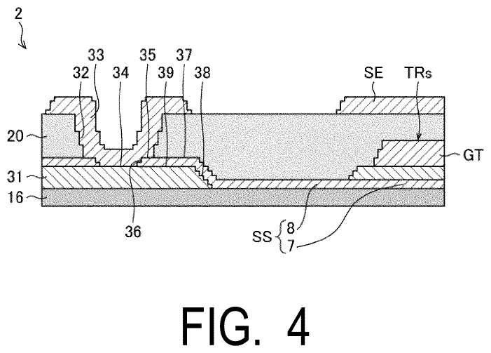

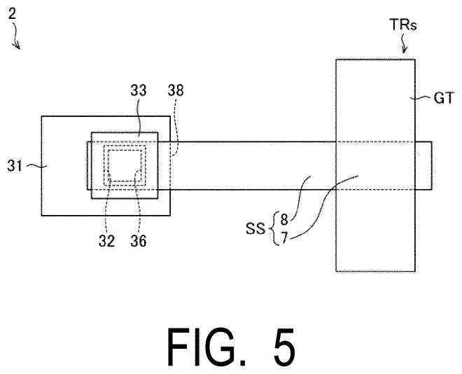

FIG. 4 is a cross-sectional view illustrating a display device 2 according to a first embodiment, and is a detailed cross-sectional view of a portion A illustrated in FIG. 2. FIG. 5 is a plan view corresponding to the above cross-sectional view. Constituent elements similar to the constituent elements described above are denoted by the same reference numerals, and detailed descriptions thereof will not be repeated.

The display device 2 includes a substrate 12, a first electrode 31 (conductive film) positioned above the substrate 12, an oxide semiconductor film SS positioned above the first electrode 31 and including a channel portion 7 and a conductor portion 8, the conductor portion 8 being in contact with the first electrode 31, a second interlayer insulating film 20 positioned above the oxide semiconductor film SS and including a contact hole 32 overlapping the first electrode 31 in a plan view, and a contact electrode 33 made of a fourth metal layer and including a portion located in the contact hole 32 and being in contact with the first electrode 31 and the conductor portion 8.

As illustrated in FIG. 5, the conductor portion 8 overlaps the contact hole 32 in a plan view.

The contact electrode 33 is in contact with an exposed face 34 of the first electrode 31 formed by the contact hole 32 and is also in contact with an exposed face 35 of the conductor portion 8.

The exposed face 35 of the conductor portion 8 is included in an upper face 37 of the conductor portion 8.

The conductor portion 8 riding on the first electrode 31 includes an opening 36 overlapping the contact hole 32 in a plan view on the first electrode 31.

Note that, the opening 36 may be located at a position corresponding to an end face of the tapered contact hole 32.

The conductor portion 8 is in contact with an end face 38 and an upper face 39 of the first electrode 31.

The display device 2 includes a first transistor TRs including the channel portion 7. The first transistor TRs has a top gate structure.

The display device 2 includes a second transistor TRp including polysilicon in a channel portion.

The first electrode 31 is in contact with a crystalline silicon semiconductor film PS via a contact hole penetrating a first interlayer insulating film 16 and a first gate insulating film 15.

The display device 2 includes a subpixel SP including a light-emitting element X, the second transistor TRp functioning as a drive transistor for controlling a current value of the light-emitting element X, and the first transistor TRs. The first transistor TRs is electrically connected to a control terminal of the second transistor TRp or an anode of the light-emitting element X.

The first transistor TRs may be a first initialization transistor T1, a threshold value control transistor T2, and a second initialization transistor T7 of a pixel circuit PK illustrated in FIG. 3.

The first electrode 31 preferably contains molybdenum. Alternatively, the first electrode 31 may be a layered film containing copper or aluminum.

The oxide semiconductor film ss preferably contains an InGaZnO-based semiconductor.

The contact electrode 33 preferably contains at least one of titanium and aluminum.

The display device 2 constituted as described above is manufactured as follows.

First, PI to be the substrate 12 is film-formed on glass. A base coat film 3 made of an insulating material is formed. Next, a silicon semiconductor film is formed, and after crystallized, patterning is performed to form a crystalline silicon semiconductor film PS. Then, the first gate insulating film 15 is formed. A first metal layer is formed and patterned to form a first gate electrode GE. Next, the first interlayer insulating film 16 is formed. Thereafter, the contact hole is formed in the first interlayer insulating film 16.

A second metal layer is formed and patterned to form the first electrode 31. Next, the oxide semiconductor film SS is formed and patterned. Then, a second gate insulating film 18 is formed. A third metal layer is formed and patterned to form a second gate electrode GT. Next, the second gate insulating film 18 is patterned. Then, the second interlayer insulating film 20 is formed.

The contact hole 32 is formed in the second interlayer insulating film 20. Then, the opening 36 is formed in the conductor portion 8. Thereafter, a fourth metal layer is formed and patterned to form the contact electrode 33 and a second electrode SE.

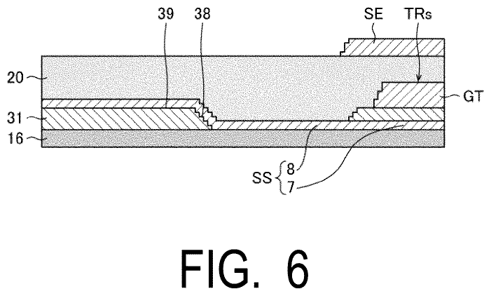

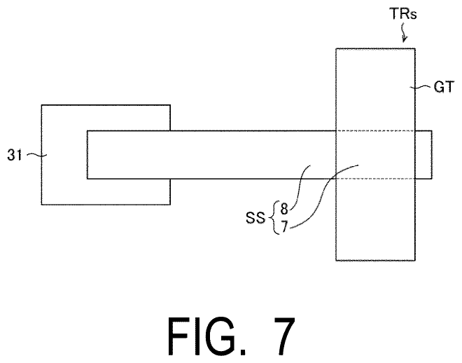

FIG. 6 is a cross-sectional view of a display device according to a comparative example. FIG. 7 is a plan view of the above display device. Constituent elements similar to the constituent elements described above are denoted by the same reference numerals, and detailed descriptions thereof will not be repeated.

As illustrated in FIG. 6 and FIG. 7, when a structure in which the oxide semiconductor film SS and the first electrode 31 containing molybdenum are in direct contact with each other is employed, the connection between the oxide semiconductor film SS and the first electrode 31 may have high resistance.

It is considered that this is because surface oxidation occurs in the first electrode 31 due to the influence of oxygen in the oxide semiconductor film SS and connection resistance between the oxide semiconductor film SS and the first electrode 31 increases. In addition, there is also a case that step disconnection of the conductor portion 8 may occur in a region where the conductor portion 8 of the oxide semiconductor film SS rides over the tapered end face 38 of the first electrode 31, and the connection resistance between the oxide semiconductor film SS and the first electrode 31 may increase.

Therefore, in the first embodiment, as illustrated in FIG. 4, the opening 36 is formed in the conductor portion 8 of the oxide semiconductor film SS over the first electrode 31, the contact hole 32 is formed in the second interlayer insulating film 20, and the contact electrode 33 is disposed in the contact hole 32.

Thus, the first electrode 31 and the contact electrode 33 come into contact with each other, and the contact electrode 33 comes into contact with the conductor portion 8 of the oxide semiconductor film SS. Therefore, the first electrode 31 is connected to the conductor portion 8 of the oxide semiconductor film SS via the contact electrode 33.

Thus, even when the connection resistance between the oxide semiconductor film SS and the first electrode 31 increases, a current flows via the contact electrode 33. Therefore, it is possible to suppress an increase in the connection resistance.

### Second Embodiment

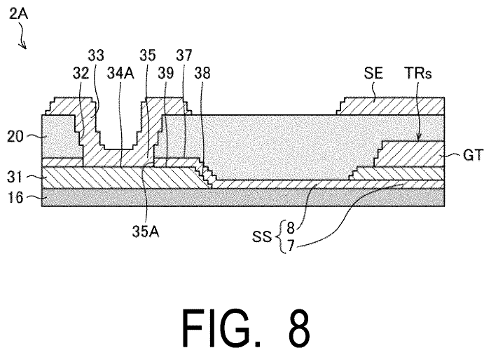

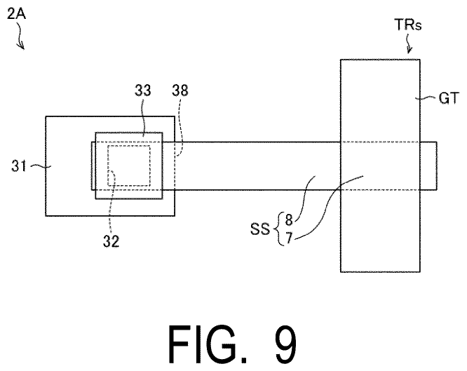

FIG. 8 is a cross-sectional view of a display device 2A according to a second embodiment. FIG. 9 is a plan view corresponding to the above cross-sectional view. Constituent elements similar to the constituent elements described above are denoted by the same reference numerals, and detailed descriptions thereof will not be repeated.

An exposed face 35A of a conductor portion 8 of an oxide semiconductor film SS is included in an end face of the conductor portion 8.

When a contact hole 32 is formed in a second interlayer insulating film 20, the conductor portion 8 of the oxide semiconductor film SS may be etched to form a ring contact structure in which an end face of the second interlayer insulating film 20 and the end face (exposed face 35A) of the conductor portion 8 are disposed on the same plane, as illustrated in FIG. 8.

Depending on the etching conditions for the second interlayer insulating film 20, the conductor portion 8 of the oxide semiconductor film SS can also be etched, and the ring contact structure illustrated in FIG. 8 is formed.

### Third Embodiment

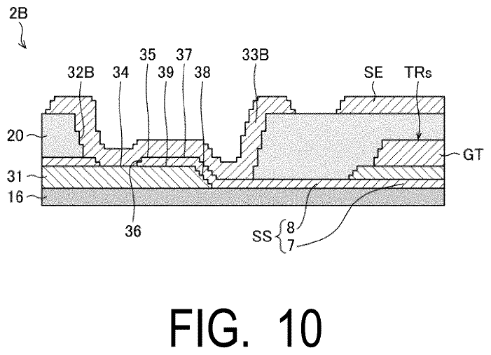

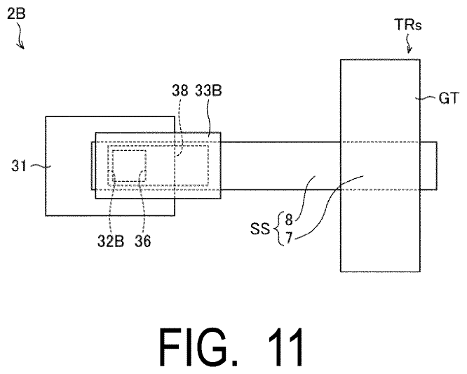

FIG. 10 is a cross-sectional view of a display device 2B according to a third embodiment. FIG. 11 is a plan view corresponding to the above cross-sectional view. Constituent elements similar to the constituent elements described above are denoted by the same reference numerals, and detailed descriptions thereof will not be repeated.

The display device 2B includes a contact hole 32B. The contact hole 32B overlaps an end face 38 of a first electrode 31 in a plan view.

In this manner, the contact hole 32B is formed and a contact electrode 33B is disposed also on the end face 38 of the first electrode 31. As a result, even when step disconnection of the conductor portion 8 occurs at the tapered end face 38 of the first electrode 31 and the connection resistance between the oxide semiconductor film SS and the first electrode 31 increases, a current flows between the oxide semiconductor film SS and the first electrode 31 via the contact electrode 33B. Therefore, it is possible to suppress an increase in the connection resistance between the oxide semiconductor film SS and the first electrode 31.

The display device 2B includes the contact electrode 33B including a portion located in the contact hole 32B and being in contact with the first electrode 31 and the conductor portion 8. The conductor portion 8 overlaps the contact hole 32B in a plan view. The contact electrode 33B is in contact with an exposed face 34 of the first electrode 31 and an exposed face 35 of the conductor portion 8 formed by the contact hole 32B. The exposed face 35 of the conductor portion 8 is included in an upper face 37 of the conductor portion 8.

The conductor portion 8 riding on the first electrode 31 includes an opening 36 overlapping the contact hole 32B in a plan view on the first electrode 31. The conductor portion 8 is in contact with the end face 38 and an upper face 39 of the first electrode 31.

### Fourth Embodiment

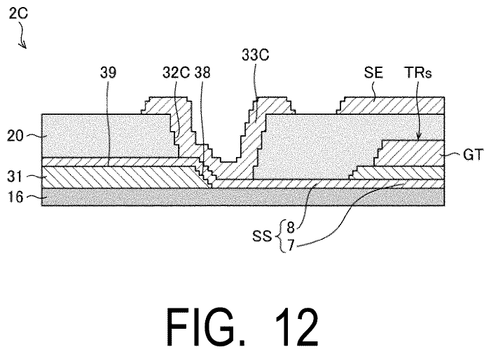

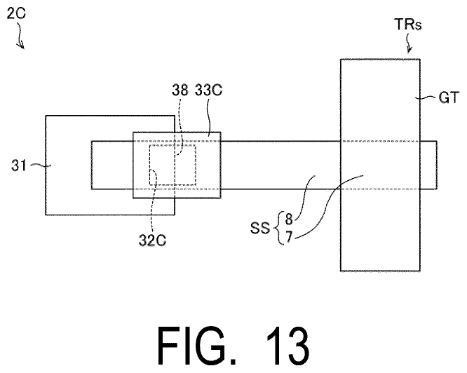

FIG. 12 is a cross-sectional view of a display device 2C according to a fourth embodiment. FIG. 13 is a plan view corresponding to the above cross-sectional view. Constituent elements similar to the constituent elements described above are denoted by the same reference numerals, and detailed descriptions thereof will not be repeated.

The display device 2C includes a first electrode 31, an oxide semiconductor film SS in which a conductor portion 8 covers an end face 38 of the first electrode 31, a second interlayer insulating film 20 positioned above the oxide semiconductor film SS and including a contact hole 32C overlapping the end face 38 of the first electrode 31 in a plan view, and a contact electrode 33C including a portion located in the contact hole 32C and being in contact with the conductor portion 8.

In this manner, the contact hole 32C and the contact electrode 33C may be disposed on the end face 38 of the first electrode 31.

The display device 2C includes the first electrode 31, the oxide semiconductor film SS positioned above the first electrode 31 and including a channel portion 7 and the conductor portion 8, the conductor portion 8 covering the end face 38 of the first electrode 31, the conductor portion 8 being in contact with the first electrode 31, the second interlayer insulating film 20 positioned above the oxide semiconductor film SS and including the contact hole 32C overlapping the end face 38 of the first electrode 31 in a plan view, and the contact electrode 33C including a portion located in the contact hole 32C and being in contact with the conductor portion 8.

Even when step disconnection of the oxide semiconductor film SS occurs at a portion riding on the end face 38 of the first electrode 31 because the thickness of the oxide semiconductor film SS is very thin with respect to the thickness of the first electrode 31 and a connection failure occurs between the first electrode 31 and the oxide semiconductor film SS, a current flows between the step-disconnected oxide semiconductor films SS via the contact electrode 33C since the contact electrode 33C exists in the position above. Therefore, the connection failure is prevented.

### Fifth Embodiment

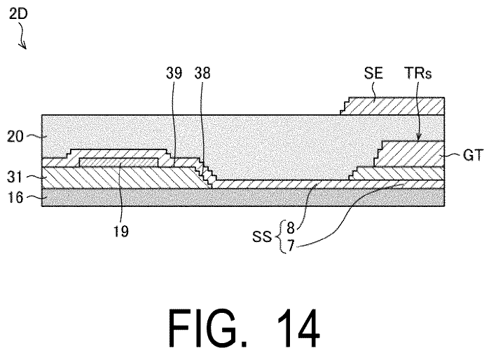

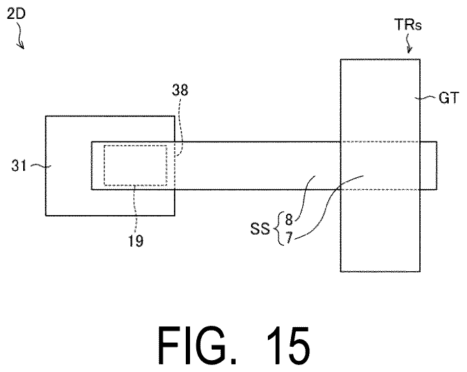

FIG. 14 is a cross-sectional view of a display device 2D according to a fifth embodiment. FIG. 15 is a plan view corresponding to the above cross-sectional view. Constituent elements similar to the constituent elements described above are denoted by the same reference numerals, and detailed descriptions thereof will not be repeated.

The display device 2D includes a first electrode 31, an oxide semiconductor film SS positioned above the first electrode 31 and including a channel portion 7 and a conductor portion 8, the conductor portion 8 overlapping the first electrode 31 in a plan view, a buffer film 19 located between the first electrode 31 and the conductor portion 8 and including an oxide semiconductor including an oxygen content lower than that of the conductor portion 8.

The conductor portion 8 of the oxide semiconductor film SS covers an end face 38 of the first electrode 31.

As a cause of an increase in the connection resistance between the oxide semiconductor film SS and the first electrode 31, there is surface oxidation of the first electrode 31 due to oxygen contained in the oxide semiconductor film SS. Therefore, in the present embodiment, in order to prevent oxidation of a surface of the first electrode 31, the buffer film 19 having an oxygen content lower than that of the conductor portion 8 is disposed between the oxide semiconductor film SS and the first electrode 31.

The display device 2D can also be manufactured by continuously forming the buffer film 19 and the oxide semiconductor film SS.

The buffer film 19 is formed in a reduced concentration of oxygen raw material lower than the concentration of the oxide semiconductor film SS.

### Sixth Embodiment

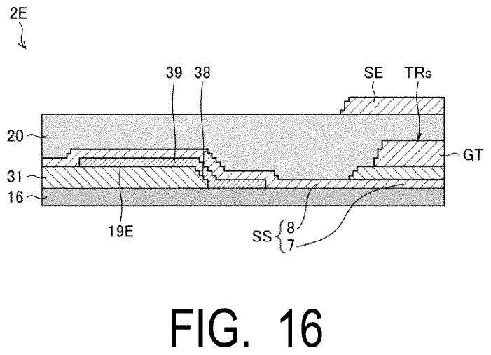

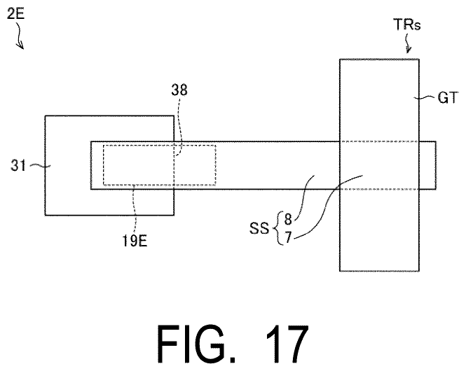

FIG. 16 is a cross-sectional view of a display device 2E according to a sixth embodiment. FIG. 17 is a plan view corresponding to the above cross-sectional view. Constituent elements similar to the constituent elements described above are denoted by the same reference numerals, and detailed descriptions thereof will not be repeated.

The display device 2E includes a first electrode 31, an oxide semiconductor film SS including a channel portion 7 and a conductor portion 8, the conductor portion 8 overlapping the first electrode 31 in a plan view, a buffer film 19E located between the first electrode 31 and the conductor portion 8 and including an oxide semiconductor including an oxygen content lower than that of the conductor portion 8.

The buffer film 19E covers an end face 38 of the first electrode 31.

In this way, by forming the buffer film 19E from an upper face 39 of the first electrode 31 to a tapered end face 38, even when step disconnection of the conductor portion 8 occurs at the tapered end face 38 of the first electrode 31 and the connection resistance between the oxide semiconductor film SS and the first electrode 31 increases, a current flows between the oxide semiconductor film SS and the first electrode 31 via the buffer film 19E. Therefore, it is possible to suppress an increase in the connection resistance between the oxide semiconductor film SS and the first electrode 31.

The display device 2E can also be manufactured by continuously forming the buffer film 19E and the oxide semiconductor film SS.

The buffer film 19E is formed in a reduced concentration of oxygen raw material lower than the concentration of the oxide semiconductor film SS.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A display device, comprising:
a substrate;
a conductive film positioned above the substrate;
an oxide semiconductor film positioned above the conductive film and including a channel portion and a conductor portion, the conductor portion being in contact with the conductive film;
an interlayer insulating film positioned above the oxide semiconductor film and including a contact hole overlapping the conductive film in a plan view; and
a contact electrode including a portion located in the contact hole and positioned above the interlayer insulating film,
wherein the contact electrode is in contact with respective exposed faces of the conductive film and the conductor portion formed by the contact hole.

2. The display device according to claim 1,
wherein the conductor portion overlaps the contact hole in a plan view.

3. The display device according to claim 1,
wherein the exposed face of the conductor portion is included in an upper face of the conductor portion.

4. The display device according to claim 1,
wherein the conductor portion includes an opening overlapping the contact hole in a plan view.

5. The display device according to claim 4,
wherein the exposed face of the conductor portion is included in an end face of the

6. The display device according to claim 1,
wherein the conductor portion is in contact with an end face and an upper face of the conductive film.

7. The display device according to claim 6,
wherein the contact hole overlaps the end face of the conductive film in a plan view.

8. The display device according to claim 1, comprising:
a first transistor including the channel portion and the conductor portion,
wherein the first transistor has a top gate structure.

9. The display device according to claim 8, comprising:
a second transistor including polysilicon in a channel portion.

10. The display device according to claim 9, comprising:
a subpixel including a light-emitting element, the second transistor configured to function as a drive transistor, and the first transistor,
wherein the first transistor is electrically connected to a control terminal of the second transistor or an anode of the light-emitting element.

11. A display device, comprising:
a substrate;
a conductive film positioned above the substrate;
an oxide semiconductor film positioned above the conductive film and including a channel portion and a conductor portion, the conductor portion covering an end face of the conductive film, the conductor portion being in contact with the conductive film;
an interlayer insulating film positioned above the oxide semiconductor film and including a contact hole overlapping the end face in a plan view; and
a contact electrode including a portion located in the contact hole and being in contact with the conductor portion.

12. A display device, comprising:
a substrate;
a conductive film positioned above the substrate;
an oxide semiconductor film positioned above the conductive film and including a channel portion and a conductor portion, the conductor portion overlapping the conductive film in a plan view; and
a buffer film located between the conductive film and the conductor portion and including an oxide semiconductor including an oxygen content lower than that of the conductor portion.

13. The display device according to claim 12,
wherein the conductor portion covers an end face of the conductive film.

14. The display device according to claim 12,
wherein the buffer film covers the end face of the conductive film.

15. The display device according claim 1,
wherein the conductive film includes molybdenum.

16. The display device according to claim 15,
wherein the oxide semiconductor film includes an InGaZnO-based semiconductor.

17. The display device according to claim 1,
wherein the conductive film includes molybdenum and the contact electrode includes at least one of titanium and aluminum.

18. A method of manufacturing the display device according to claim 12, comprising:
forming the buffer film and the oxide semiconductor film continuously.

19. The method of manufacturing the display device according to claim 18,
wherein the buffer film is formed in a reduced concentration of oxygen raw material lower than the concentration of the oxide semiconductor film.
